(19) United States
(12) Patent Application Publication
(10) Pub. No.: US 2001/0053616 A1
(43) Pub. Date: Dec. 20, 2001

(54) Method and an apparatus for manufacturing multilayer electronic part

(75) Inventors: Mutsuo Nakazawa, Tokyo (JP); Mitsuo Ueno, Tokyo (JP); Akira Yamanaka, Tokyo (JP); Katsuhiro Oyama, Tokyo (JP); Satoshi Takakuwa, Tokyo (JP); Hiroshi Takahashi, Tokyo (JP)

Correspondence Address: LOWE HAUPTMAN GOPSTEIN GILMAN & BERNER, LLP, Suite 310, 1700 Diagonal Road, Alexandria, VA, 22314, US

(73) Assignee: TAIYO YUDEN CO., LTD.

(21) Appl. No.: 09/736,407

(22) Filed: Dec. 15, 2000

(30) Foreign Application Priority Data
Dec. 16, 1999 (JP) H11-357509

(51) Int. Cl. H01L 21/26; H01L 21/42

(52) U.S. Cl. 438/795

(57) ABSTRACT

A method of manufacturing multilayer electronic parts including a processing step asnd an apparatus for manufacturing multilayer electronic parts including a processing apparatus for subjecting a green sheet to a predetermined processing by irradiating it with the laser beam. A green sheet attached to the periphery of one of two drums is subjected to the predetermined processing by irradiating it with the laser beam from a beam irradiation means while allowing the drum to rotate about a drum's centerline as an axis and travel in the direction of the drum's centerline. And while subjecting the green sheet to the processing, processed green sheets are detached from the periphery of the other drum and unprocessed green sheets are attached to it with a sheet attaching/detaching means.

### BACKGROUND OF THE INVENTION

(i) Field of the Invention

The present invention relates to a method and an apparatus useful for manufacturing of multilayer electronic parts such as a multilayer chip inductor

(ii) Description of the Related Art

A multilayer chip inductor known as one type of multilayer ceramic electronic part has been manufactured in the following manner.

First ceramic a green sheet having a size small enough to permits a plurality of them to be subjected to forming at a time hereinafter referred to as, simply, a green sheet) are prepared, and a matrix of through holes is formed thereon to have a predetermined arrangement. Formation of these through holes is achieved by repeating the following operations: first, forming a row of through holes on the green sheet by irradiating the green sheet with a laser beam intermittently while allowing an XY table on which the green sheet are held to travel in the X direction at a predetermined speed; performing a column change by stopping the table and then allowing it to travel a predetermined distance in the Y direction; and again irradiating the green sheet with a laser beam intermittently while allowing the table to travel in the X direction at a predetermined speed.

Then the entire surface of the green sheet having a matrix of through holes formed thereon is subjected to screen printing in a predetermined pattern with coil conductor paste. The patterns of the conductor paste are formed in numbers corresponding to the number of the parts to be formed, and part of the paste pattern is packed into the through holes while printing.

Then the green sheet having paste patterns, of which number corresponds to the number of the parts to be formed, formed thereon and the green sheet having neither through holes nor paste patterns formed thereon are stacked and pressed. These stacking and pressing operations allow the paste patterns among the sheets to be connected to each other via the paste packed into the through holes and take the form of a coil.

Then the multilayer sheet is cut to a unit size corresponding to that of the parts, and the multilayer chips thus obtained are subjected to firing. Lastly, the outer surface of the chips having been subjected to firing is coated with electrode paste and baked so as to form an external electrode, and if necessary, a solder film is formed on the surface thereof

In the above described method of manufacturing a multilayer electronic part which includes a processing step of forming a matrix of through holes on a green sheet, reducing the time required for the above processing step is one of the most important subjects to improve the efficiency of manufacturing parts, in other words, reduce the unit cost of the manufactured parts.

However, in the above described process, that is, in the process of forming the matrix of through holes on a green sheet by irradiating it with laser beam intermittently while allowing the green sheet on the table to travel in the X, Y directions, it is necessary, when allowing the table to travel in the X direction so as to form the row of through holes, to ensure an accelerating area, where the table does not reach a predetermined speed yet and is still accelerated, as well as a reducing area, where the table is slowed down to be stopped, in the X direction. And at it time, it is also necessary to ensure the time for allowing the table, which is stopped after a row of through holes has been formed thereon, to travel in the Y direction and stopping it again, every time column change is performed. In other words, during processing, the table has to travel a larger distance in the X direction for the above accelerating and reducing areas. And moreover, since the time required for the column changes increases in proportion to the number of the column changes, even if the traveling speed of the table is increased in both the X and Y directions, a fair amount of time is required for forming a desired matrix of through holes on a green sheet.

After forming the predetermined matrix of through holes on the green sheet on the table, the operations are needed of detaching the processed green sheet from the table and of attaching another unprocessed green sheet on it, while stopping the table. Thus, the processing is stopped temporarily due to the operation of detaching and attaching sheets from and on the table, this causes increase in time required for the processing step.

### SUMMARY OF THE INVENTION

Accordingly, the object of the present invention is to provide a method of manufacturing a multilayer electronic part which enables shortening the time required for the processing step of forming a matrix of through holes on a green sheet, and hence, improving the efficiency of part manufacturing, and an apparatus suitably used for carrying out the above method.

In order to achieve the above object, the method of manufacturing a multilayer electronic part according to the present invention includes a step of subjecting a green sheet to a predetermined processing by irradiating the green sheet with a laser beam, said processing step is performed by: using some of two or more drums, the periphery of which the green sheet can be attached to and detached from, as a processing-side drum and the rest thereof as a non-processing-side drum; subjecting the green sheet attached to the periphery of the processing-side drum to the predetermined processing by irradiating it with the laser beam from at least one beam irradiation means while allowing the processing-side drum to rotate about the drum's centerline as an axis, and travel in the direction of the drum's centerline; and detaching a processed green sheet from the periphery of the non-processing-side drum and attaching an unprocessed green sheet on it with at least one sheet attaching/detaching means while subjecting the green sheet to the predetermined processing.

According to this manufacturing method, the two operations can be performed at it time of: subjecting the green sheet attached to the periphery of the processing-side drum to the predetermined processing by irradiating it with the laser beam while allowing the processing-side drum to rotate about the drum's centerline as the axis and travel in the direction of the drum's centerline; and detaching the processed green sheet from the periphery of the non-processing-side drum and attaching the unprocessed green sheet on it. In other wards, the predetermined processing can be performed continuously without stopping the processing due to the operations of attaching/detaching sheets from and on the periphery of the non-processing-side drum, this enables shortening the time required for the step of subjecting the green sheet to the predetermined processing greatly, and hence, improving the efficiency of part manufacturing, and moreover, contributes to reduction in the unit cost of the manufactured parts.

The apparatus for manufacturing a multilayer electronic part according to the present invention includes an apparatus for subjecting a green sheet to a predetermined processing by irradiating it with a laser beam, said processing apparatus comprising: two or more drums the periphery of which the green sheet can be detached from and attached to, some of the two or more drums being used as a processing-side drum and the rest thereof being used as a non-processing-side drum; a drum driving means allowing the processing-side drum to rotate about the drum's centerline as an axis and travel in the direction of the drum's centerline; at least one beam irradiation means capable of irradiating the laser beam toward the periphery of the processing-side drum; at least one sheet attaching/detaching means capable of attaching the green sheet to and detaching it from the periphery of the non-processing-side drum; a process control means for controlling the drum driving means and beam irradiation means so that the beam irradiation means can irradiate the green sheet attached to the periphery of the processing-side drum with the laser beam while allowing the processing-side drum to rotate about the drum's centerline as the axis and travel in the direction of the drum's centerline; and a sheet attaching/detaching control means for controlling the sheet attaching/detaching means so that, while the green sheet on the periphery of the processing-side drum are subjected to processing, the sheet attaching/detaching means can detach a processed green sheet from the periphery of the non-processing-side drum and attach an unprocessed green sheet to it.

According to this manufacturing apparatus, the operation of subjecting the green sheet attached to the periphery of the processing-side drum to the predetermined processing by irradiating it with the laser beam while allowing the processing-side drum to rotate about the drum's centerline as the axis and travel in the direction of the drum's centerline can be performed by controlling the drum driving means and beam irradiation means with the process control means, and the operation of detaching the processed green sheet from the periphery of the non-processing-side drum and attaching the unprocessed green sheet on it can be performed by controlling the sheet attaching/detaching means with the sheet attaching/detaching control means. In other words, according to this manufacturing apparatus, the above described manufacturing method of the present invention can be carried out exactly and it effects described above can be obtained.

The foregoing and other objects, features and advantages of the present invention will become more apparent from the following detailed description of preferred embodiments of the present invention with reference to the drawings.

### BRIEF DESCRIPTION OF THE DRAWINGS

FIG. 1 is a schematic view of a configuration of a processing apparatus which is a first embodiment of the present invention;

FIG. 2 is a view showing details of drums and a table shown in FIG. 1;

FIG. 3 is a side view of FIG. 2;

FIG. 4 is a vertical section of a drums shown in FIG. 1;

FIG. 5 is a perspective view of a green sheet shown in FIG. 1;

FIG. 6 is an end view of the drum in a state where it has three green sheets attached to its periphery;

FIG. 7 is a view of a configuration of a beam irradiation machine shown in FIG. 1;

FIG. 8 is a top plan view of a sheet attaching/detaching machine shown in FIG. 1;

FIG. 9 is a side view, partially broken away, of the sheet attaching/detaching machine shown in FIG. 1;

FIG. 10 is a view illustrating an operation of the sheet attaching/detaching machine shown in FIG. 1;

FIG. 11 is a view illustrating the operation of the sheet attaching/detaching machine shown in FIG. 1;

FIG. 12 is a block diagram of a process control system of the processing apparatus shown in FIG. 1;

FIG. 13 is a side view of a drum showing the state in which a matrix of through holes is formed on a green sheet;

FIG. 14 is a view illustrating an operation of a processing apparatus according to the first embodiment of the present invention;

FIG. 15 is a side view of a drum showing another method of forming a matrix of through holes on a green sheet;

FIG. 16 is a schematic view of a configuration of a processing apparatus which is a second embodiment of the present invention;

FIG. 17 is a view of a configuration of a beam irradiation machine shown in FIG. 16;

FIG. 18 is a view illustrating an operation of the processing apparatus according to the second embodiment of the present invention;

FIG. 19 is a schematic view of a configuration of a processing apparatus which is a third embodiment of the present invention;

FIG. 20 is a view showing details of drums and a table shown in FIG. 19;

FIG. 21 is a schematic view of a configuration of a processing apparatus which is a fourth embodiment of the present invention;

FIG. 22 is a view showing an arrangement of drums shown in FIG. 21;

FIG. 23 is a schematic view of a configuration of a processing apparatus which is a fifth embodiment of the present invention;

FIG. 24 is a view showing details of a sheet attaching/detaching machine and a table shown in FIG. 23;

FIG. 25 is a view illustrating the operation of a processing apparatus according to the fifth embodiment of the present invention; and

FIG. 26 is a view showing another method of processing a green sheet.

### DESCRIPTION OF THE PREFERRED EMBODIMENTS

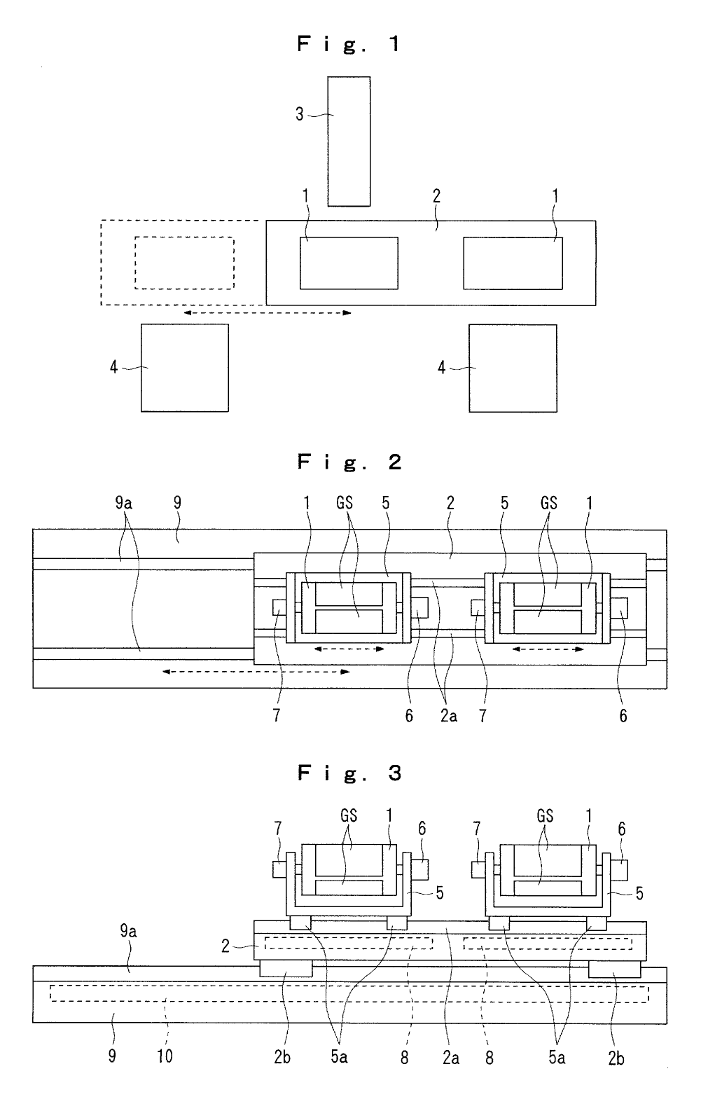

FIGS. 1 to 15 show a first embodiment of the present invention.

Referring to FIG. 1, there is shown a schematic view of a configuration of a processing apparatus which is the first embodiment. In FIG. 1, reference numeral 1 denotes two drums the periphery of which a green sheet can be detached from and attached to and numeral 2 denotes a translatable table on which the above two drums 1 are arranged. The table 2 is movable in such a manner that when one drum 1 is in a processing position (in the middle of the figure), the other drum 1 is in any one of two non-processing positions (both end portions of the figure). Numeral 3 denotes a laser beam irradiation machine, which is arranged in a position corresponding to the processing position so that it can irradiate the periphery of the drum 1 in the processing position with laser beam. Numeral 4 denotes two sheet attaching/detaching machines, which are arranged in a position corresponding to the above two non-processing positions, respectively, so that they can detach a processed green sheet from the periphery of the drum 1 in any one of the two non-processed position and attach a unprocessed green sheet on it.

In the following the concrete configuration of the apparatus shown in FIG. 1 will be described in further detail.

The two drums 1 are the same size and formed of metals such as stainless to a cylindrical form, as shown in FIG. 4, and, on the periphery thereof, numbers of fine suction holes la leading to their inside hollow are formed and arranged in a prescribed manner. Each drum 1 has a drum shaft 1b provided in the center of its both end sides, the axes of both drum shafts 1b correspond to the drum centerline, and one drum shaft 1b has a suction passageway 1c, which leads to the inside hollow, provided therein. This suction passageway 1c is connected to a suction source (not shown in the figure) such as vacuum pump via a rotary joint, and it can apply a negative pressure (suction) to each and every suction hole 1a on the periphery of each drum by the operation of the suction source. Further, each drum 1 is supported by a support stand 5 at its drum shaft 1b in a rotatable manner.

To one end of each drum shaft 1b supported by each supporting stand 5 connected is a motor 6 for rotating each drum and to the other end of it connected is an encoder 7 for detecting the rotation angle of each drum. Each supporting stand 5 has rail guides 5a provided on the lower surface of its bottom in such a manner as to allow them to mesh with a rail 2a provided on the table 2 and between the supporting stand 5 and the table 2 provided is a linear motor 8, 8 for moving each supporting stand 5 along a straight line individually. The table 2 has rail guides 2b provided its lower surface in such a manner as to allow them to mesh with a rail 9a provided on a base 9 and between the table 2 and the base 9 provided is a linear motor 10 for moving the table 2 along a straight line.

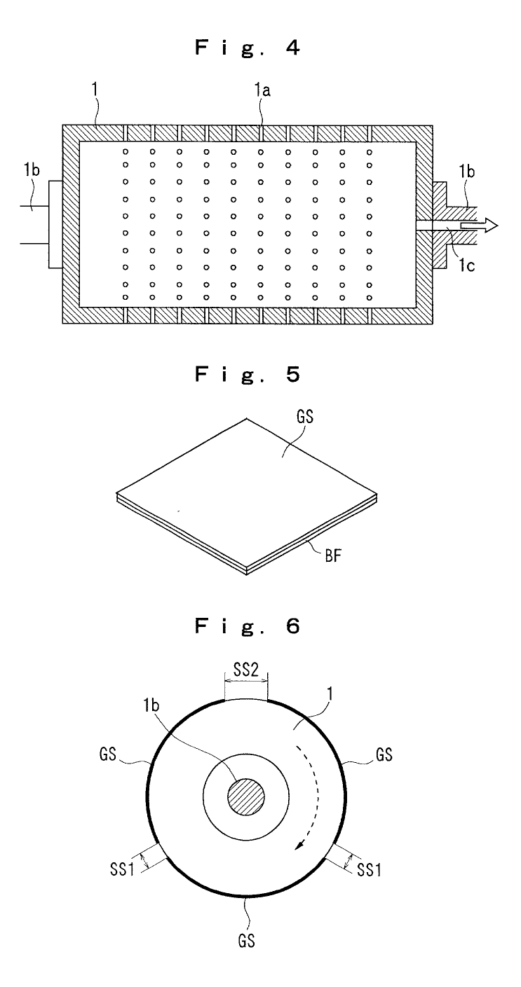

As seen from FIGS. 2 and 3, the moving direction of the table 2 and the moving direction of the each supporting stand 5 are the same, and the two drums 1 are arranged in such a manner that their centerlines are lined up laterally and their centerlines are parallel to the moving directions of the table 2 and each supporting stand 5.

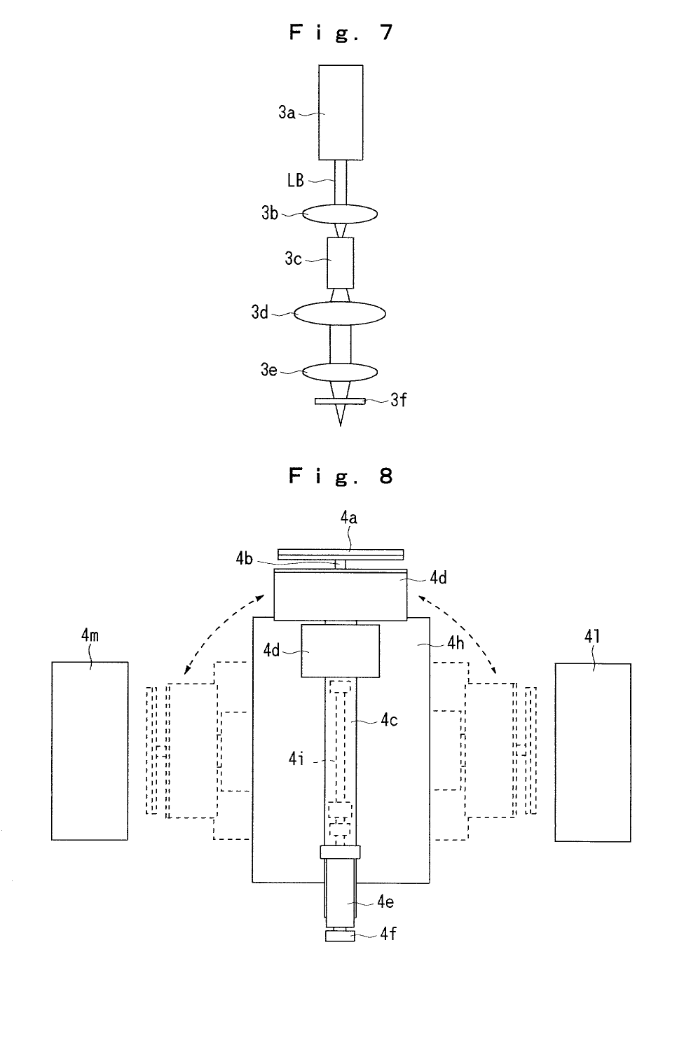

On the periphery of each drum 1 attached is the green sheet GS as shown in FIG. 5. This green sheet has a rectangular upper surface and its lower surface is backed with a base film BF consisting of flexible film such as PET. This green sheet GS can be obtained, for example, in the following procedure: preparing a ceramic slurry by mixing ferrite ceramic powder, a binder, a solvent etc.; coating a sheet base film with the ceramic slurry to a prescribed thickness and drying it; and cut this sheet article or punch it out to a prescribed size. It goes without saying that the green sheet GS can be obtained by coating a rectangular base film with the ceramic slurry, followed by drying it. As the slurry material including ceramic powder, properly prepared are those suitable for multilayer electronic parts to be manufactured, for example, multilayer chip parts such as multilayer chip inductor and multilayer composite parts such as an LC filter.

This green sheet GS is arranged in such a manner as to allow the surface of the base film BF side to come in contact with the periphery of the drum and is attached to it by the suction applied to the above described suction holes la. The green sheet GS can be easily detached from the drum's periphery by relaxing the suction. As shown in FIG. 6, in the each drum 1 shown in FIGS. 2 and 3, three green sheets GS are attached to the drum 1 in such a manner that spaces SS1 and SS2, which are almost parallel to the drum's centerline, are left between the sheets. The space SS2 is larger than the space SS1 and is used as a part of the processing-track-change-area as described afterward.

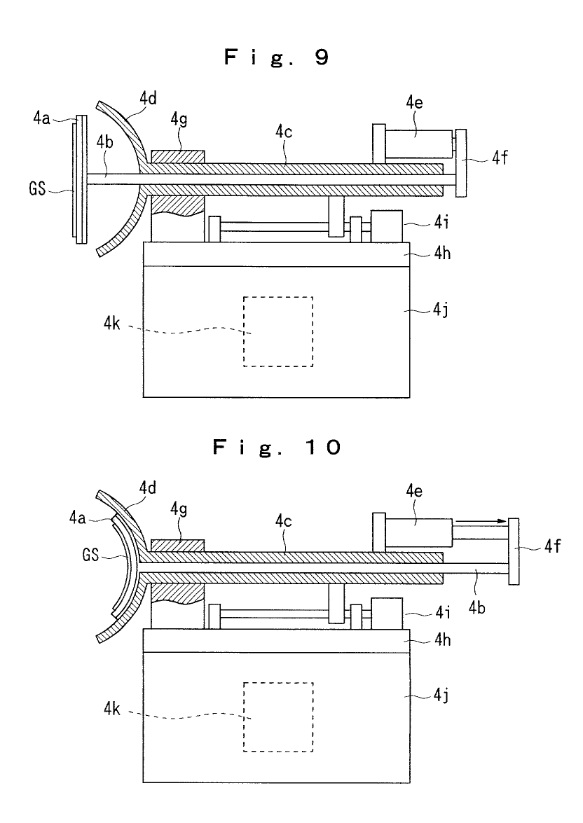

The laser beam irradiation machine 3 includes a laser oscillator 3a, a condenser lens 3b, a homogenizer 3c, a relay lens 3d, an objective lens 3e and a shielding plate 3f, as shown in FIG. 7.

Preferably the laser oscillator 3a consists of YAG laser oscillator such as CW-Q oscillation and normal pulse oscillation which oscillates fundamental wave or higher harmonic wave; however, other laser oscillators such as CO₂ laser and excimer laser can also be used. The laser beam LB outgone from the laser oscillator 3a enters the homogenizer 3c via the condenser lens 3b, and the homogeneous laser beam LB outgone from the homogenizer 3c goes through the relay lens 3d and the objective lens 3e and reaches the shielding plate 3f placed thereunder. This shielding plate 3f accepts the penetration of laser beam, in addition, it serves to prevent the objective lens 3e from being contaminated with process dust produced when irradiating the green sheet GS with the laser beam LB. As the shielding plate 3e, those obtained by forming beam passing holes on a laser beam non-transmitting plate such as metal plate, laser beam transmitting plates such as glass plate, those obtained by forming a beam transmitting portion on the laser beam non-transmitting plate, and those obtained by stacking the above plates can be used properly.

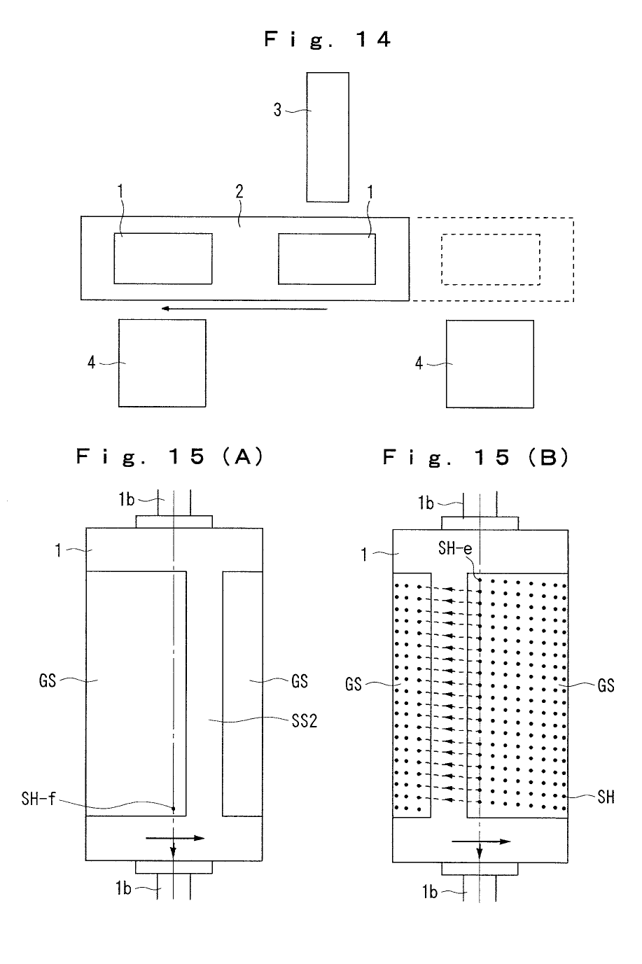

The laser beam LB reached the shielding plate 3f via the objective lens 3e penetrates the shielding plate 3f and irradiates the green sheet GS in a prescribed form, for example, in the form of a circle. The position of the green sheet GS irradiated with the laser beam LB is on the centerline of the drum 1 (refer to the alternate long and short dash line of FIG. 13), as seen from the side, and the centerline of the laser beam LB irradiating on the above position corresponds to the normal line from the center of the irradiated position of the drum 1.

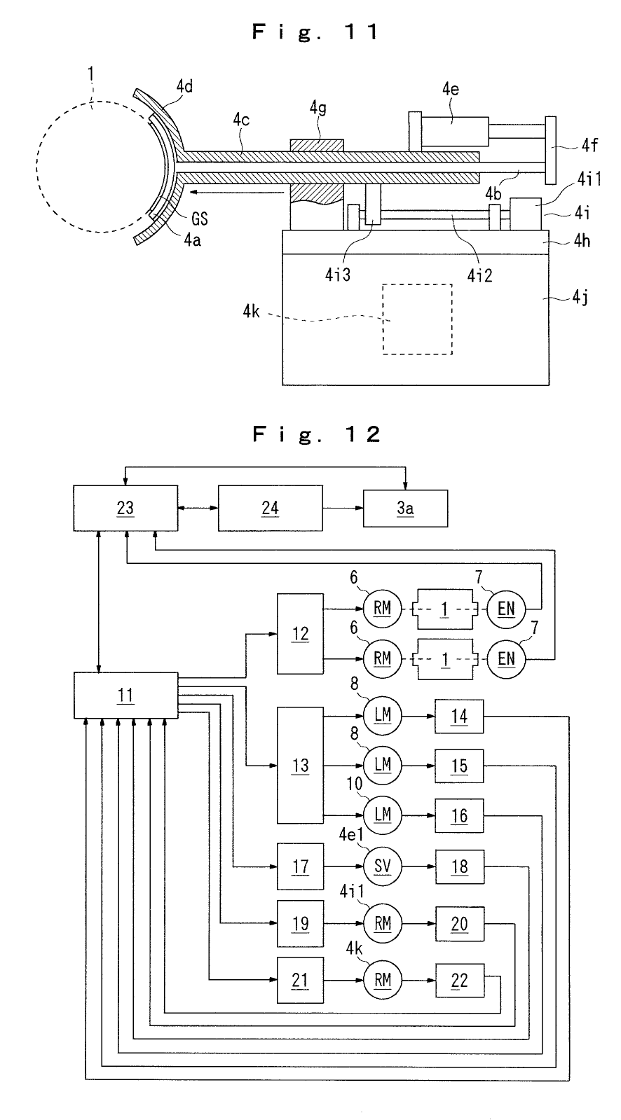

Each of the two sheet attaching/detaching machines 4 includes a flexible adsorption pad 4a, a first hollow rod 4b supporting the adsorption pad 4a, a second hollow rod 4c containing the first rod 4b in a translatable manner, a curved guide plate 4d provided on the tip of the second rod 4c, a cylinder 4e arranged on the rear end of the second rod 4c, a connecting plate 4f connecting the rod of the cylinder 4e and the first rod 4b, a guide block 4g supporting the second rod 4c in a translatable manner, a turn table 4h supporting the guide block 4g, a linear driving mechanism 4i arranged between the turn table 4h and the second rod 4c, a base 4j supporting the turn table 4h, a motor 4k for rotating the turn table, a feeder 4l l for feeding the unprocessed green sheet GS, and a storage equipment 4m for storing the processed green sheet GS, as shown FIGS. 8 and 9.

The adsorption pad 4a consists of a flexible resin or rubber material and has numbers of suction holes (not shown in the figures) which communicate with the inside hole of the first rod 4b. The inside hole of the first rod 4b is connected to a suction source (not shown in the figures), such as vacuum pump, and with the operation of the suction source a negative pressure (suction) can be applied to the entire suction holes of the adsorption pad 4a.

The linear driving mechanism 4i is to allow the second rod 4c to travel linearly. In the figure, shown is the mechanism formed by combining a motor 4i1 with a ball screw 4i2 and a nut 4i3, and the motor 4i1 and the ball screw 4i2 are arranged on the turn table 4h side and the nut 4i3 is connected to the second rod 4c. An operation of the sheet attaching/detaching machines 4 will be described in detail later.

Referring to FIG. 12, there is shown a block diagram of the process control system of the apparatus shown in FIG. 1. In FIG. 12, reference numeral 1 denotes the drums, numeral 3a the laser oscillator, numeral 4e1 a selector valve of the cylinder 4b for moving a first rod, numeral 4k the motor for rotating the turn table, numerals 6, 6 the motors for rotating drums, numerals 8, 8 the linear motors for moving supporting stands, and numeral 10 the linear motor for moving a table.

Reference numeral 11 denotes a motion controller, numeral 12 a power source for motors 6, 6, numeral 13 a power source for linear motors 8, 8, 10, numerals 14 and 15 linear scales for detecting the position of the supporting stand 5, numeral 16 a linear scale for detecting the position of the table 2, numeral 17 a power source for operating the selector valve 4e l for controlling the operation of the cylinder 4e, numeral 18 a position detector for detecting the position of the first rod 4b, numeral 19 a power source for the motor 4i1 of the linear driving mechanism 4i, numeral 20 a position detector for detecting the position of the first rod 4b, numeral 21 a power source for the motor 4k of the turn table 4h, numeral 22 a position detector for detecting the position of the turn table 4h, numeral 23 a laser emission controller, and numeral 24 a power source for the laser oscillator 3a.

From the motion controller 11 control signals for controlling the operation of the motors etc. are sent out to the power sources 12, 13, 17, 19 and 21, and from the linear scales 14, 15 and 16 and the position detectors 18, 20 and 22 position data are fed back to the motion controller 11. Further, from the motion controller 11 control signals for controlling the laser beam irradiation is sent out to the laser emission controller 23. The rotation angle signals (rotation angle quantity) of encoders 7, 7 are sent out to the laser emission controller 23, and based on these signals, control signals for controlling laser oscillation are sent out from the laser emission controller 23 to the power source 24 and the laser oscillator 3a. And to the laser emission controller 23, oscillation data (the number of irradiation times) from the laser oscillator 3a and operation data from the power source 24 are fed back.

In the following, a method of forming a matrix of through holes SH on the green sheet GS using the above described apparatus will be described.

When none of the two drums 1 have the green sheet GS attached thereon, first the table 2 is made to travel in such a manner as to allow one of the drums to face one of the sheet attaching/detaching machines 4 (refer to FIG. 1), then the operation of attaching three green sheets GS on the periphery of the drum 1 is performed using one sheet attaching/detaching machine 4 in the following manner.

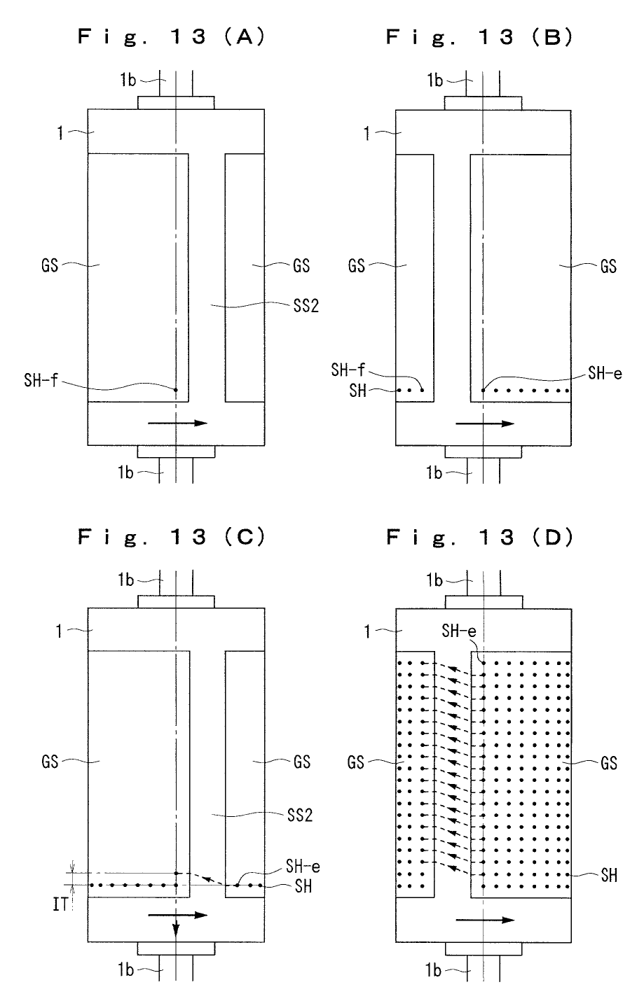

First, the turn table 4h of the sheet attaching/detaching machine 4 is rotated 90 degrees clockwise in FIG. 8, the second rod 4c is made to advance so that the adsorption pad 4a, to which suction is applied, can adsorb the unprocessed green sheet GS from the feeder 41, and after the adsorption, the second rod 4c is made to travel backward and the turn table 4h is returned to the initial position (refer to FIG. 9). Then the first rod 4b is made to travel backward so that the adsorption pad 4a can be taken in the curved guide plate 4d, and the flexible adsorption pad 4a is curved by the curved guide plate 4d (refer to FIG. 10). Then the second rod 4c is made to advance so that the base film side of the green sheet GS is allowed to come in contact with the periphery of the drum 1 in the stopped state. During this operation, suction is applied to the suction holes 1a of the drum 1, and after the green sheet comes in contact with the periphery of the drum 1, the suction having been applied to the adsorption pad 4a is relaxed so that the green sheet GS can be shifted from the adsorption pad 4a to the periphery of the drum 1 (refer to FIG. 11). After the shift of the green sheet GS, the second rod 4c is made to travel backward and the first rod 4b is returned to the initial position. After the unprocessed green sheet GS is attached to the periphery of the drum 1, the drum 1 is rotated about 120 degrees, it sheet attaching operation as above is repeated twice; thus, three green sheets GS are attached to the periphery of the drum 1.

After three green sheets GS are attached to the periphery of one drum 1, the table 2 is made to travel so that the drum 1 having the green sheet GS attached thereon faces the laser beam irradiation machine 3 (refer to FIG. 14), and the green sheets GS attached to the periphery of the drum 1 is subjected to processing with laser beam LB outgone from the laser beam irradiation machine 3 in the following manner.

First, the drum 1 is made to start to rotate by the motor 6, and after the rotation speed of the drum 1 reaches a predetermined speed, processing of a first column is started at the time the rotation angle of the drum 1 reaches a predetermined process-start-angle.

Specifically, at the time the rotation angle of the drum 1 reaches the predetermined process-start-angle, the green sheet on the periphery of the drum is exposed to laser beam LB so as to form a first through hole SH-f (refer to FIG. 13( A)). Then the green sheet are exposed to laser beam LB at intervals of a predetermined rotation angle intermittently, so that a row having a prescribed number of through holes SH, which are located at uniform intervals in the circumference direction, is formed on each of the three green sheets GS (refer to FIG. 13(B)). In the example shown in figures, of the three green sheets GS shown in FIG. 6, the green sheet GS adjacent to the space SS2 on its left side is selected as a first green sheet to form the through hole SH.

Formation of through holes by the use of the laser beam irradiation is performed in such a manner as to melt and evaporate the beam irradiated portion of the green sheet GS utilizing the energy of the irradiated laser beam LB. And in this laser beam irradiation, preferably through holes SH are formed on the green sheet GS alone without processing the base film BF. And in order to prevent the periphery of the drum 1 from being exposed to the laser beam LB, the irradiation of the laser beam LB is not performed on the angular area containing the spaces SS1 and SS2, as shown in FIG. 6.

Once processing of the first column is started, whether the number of the processing times on the first column (the total number of the through hole SH) reaches the predetermined number or not is judged. And after a last through hole SH-e of the first column is formed on the third green sheet GS (refer to FIG. 13(B)), the processing column is changed at the time the rotation angle of the drum 1 reaches the process-column-change-angle.

Specifically, at the time the rotation angle of the drum 1 reaches a predetermined process-column-change-angle, the supporting stand 5 of the drum 1 is made to travel the predetermined distance of IT in the direction of the drum centerline by the linear motor 8 (refer to FIG. 13(C)). Thus, the column change is performed by changing the processing track by the distance of IT in the direction of the drum centerline utilizing the area containing the space SS2 shown in FIG. 6. It goes without saying that, during this processing track change, irradiation of laser beam LB is not performed.

After changing the column, a row having the predetermined number of through holes SH, which are located at uniform intervals in the circumference direction, is formed on each of the three green sheets GS, just as described above. When the number of the processing times reaches the predetermined number on the second column, the process column is changed in it manner as above. After this, the formation of through hole rows and column change are repeated until the number of the through hole rows reaches the predetermined number of the process columns. At the time a last through hole SH-e of the last column is formed on the third green sheet GS and the number of the columns of through holes SH reaches a predetermined number of the process columns, a given series of processes are completed (refer to FIG. 13(D)).

On the other hand, while the green sheets GS attached to the periphery of one drum 1 are being subjected to processing of forming the matrix of through holes, the operation of attaching three unprocessed green sheets on the periphery of the other drum 1 is performed with the other sheet attaching/detaching machine 4 in it procedure as described above, making use of this processing time.

After completion of the predetermined processing on the green sheets GS attached to the periphery of one drum 1, the table 2 is made to travel so that the other drum 1 having the unprocessed green sheet GS attached thereon faces the laser beam irradiation machine 3 (refer to FIG. 1), and the processes are performed on the green sheets GS attached to the periphery of the drum 1 with the laser beam LB outgone from the laser beam irradiation machine 3 in it procedure as described above.

While the green sheets GS attached to the periphery of the other drum 1 are being subjected to processing of forming the through hole matrix, the three processed green sheets GS are detached from the periphery of one drum 1, on which the processing has been already completed, with the sheet attaching/detaching machine 4, making use of the processing time, and the operation of attaching another unprocessed three green sheets GS on the periphery of it drum 1 is performed in the following manner.

First, the first rod 4b of the sheet attaching/detaching machine 4 is made to travel backward so that the adsorption pad 4a is taken in the curved guide 4d, and the flexible adsorption pad 4a is curved by the curved guide 4d (refer to FIG. 10). Then the second rod 4c is made to advance so that the adsorption pad 4a to which suction is applied can come in contact with the processed green sheet 1 attached to the periphery of the drum 1. During this operation, suction of the suction holes 1a of the drum 1 is relaxed, and after the processed green sheet comes in contact with the adsorption pad 4a, suction is applied to the adsorption pad 4a so that the processed green sheet GS can be shifted from the periphery of the drum 1 to the adsorption pad 4a (refer to FIG. 11). After detaching one processed green sheet GS from the periphery of the drum 1, the second rod 4c is made to travel backward while the first rod 4b is returned to the initial position (refer to FIG. 9). After the turn table 4h is rotated 90 degrees counterclockwise in FIG. 8, the second rod 4c is made to advance, suction of the adsorption pad 4a is relaxed, and the processed green sheet GS is stored in the storage equipment 4m. After the storage, the second rod 4c is made to travel backward and the turn table 4h is returned to the initial position (refer to FIG. 9). After detaching one processed green sheet from the periphery of the drum 1 and storing it in the storage equipment 4m, the drum 1 is rotated about 120 degrees, it operation of sheet separation as above is repeated twice, so that the three processed green sheets GS are detached from the periphery of the drum 1 on which a given series of processes have been completed. Subsequently, the operation of attaching another three unprocessed green sheet GS on the periphery of one drum 1 from which the processed green sheet have been already detached is performed in it procedure as described above.

After this, the two operations, that is, performing the predetermined processing (formation of the through hole matrix) by exposing the three green sheets GS attached to the periphery of the drum 1 to laser beam LB intermittently while rotating one drum 1 and allowing it to travel in the drum centerline direction and detaching the three processed green sheet from the periphery of the other drum 1 and attaching another unprocessed three green sheets GS on it, making use of the above processing time, are repeated alternately while changing the drum position by allowing the table 2 to travel every time a given series of processes are completed.

As described above, according to the processing apparatus and processing method of the first embodiment, while performing the predetermined processing (formation of the through hole matrix) by exposing the three green sheets GS attached to the periphery of one drum 1 to the laser beam LB intermittently while rotating the drum 1 and allowing it to travel in the drum centerline direction, another operation of detaching the three processed green sheets from the periphery of the other drum 1 and attaching another unprocessed three green sheets GS on it can be performed making use of the above processing time. In other words, the predetermined processing is never stopped due to operations of detaching/attaching sheets from/on the drum's periphery and can be performed continuously; as a result, the processing apparatus and processing method offer the advantages of greatly reducing the time required for the predetermined processing of the green sheet GS and improving the efficiency of part manufacturing, in addition, of greatly contributing to the reduction in unit cost of the manufactured part.

In terms of the drum 1 which is involved in the predetermined processing, since the formation of the through hole matrix on each of the three green sheets GS attached to the periphery of the drum can be performed without stopping the rotation of the drum 1, it is possible to form on the order of 1,000 to 10,000 through holes SH on the green sheet per second. Thus, the processing apparatus and processing method of the first embodiment offers the advantage of greatly reducing the time required for the formation of a desired through hole matrix on the green sheet GS, compared with the method currently in use.

Further, in terms of the drum 1 from and on which green sheets are detached and attached, the unprocessed green sheets GS can be attached to the periphery of the drum 1 and the processed green sheet GS can be detached from it in a state where they are adapted to the curvature of the periphery. Thus, the processing apparatus and processing method of the first embodiment offers the advantage of performing the operation of detaching/attaching sheets from/on the periphery of the drum 1 more efficiently and properly.

By the way, in the first embodiment described above, three green sheets GS are attached to the periphery of the drum 1; however, in cases where two or less green sheet(s) GS or four or more green sheets GS are attached to it, it processing and it sheet detaching/attaching operations as described above can be performed.

Further, in the first embodiment described above, three green sheets GS are attached to the periphery of the drum 1 in such a manner as to leave spaces between the two adjacent green sheets and one space SS2 is used as part of the process-track-change-area; however, if the area equivalent to the above space SS2 is ensured on the green sheet side, such the space is not always needed, and it processing as described above can be performed even when attaching the green sheet with no spaces therebetween.

In the first embodiment described above, through holes SH are formed on the green sheet with one Q switch pulse; however, in cases where perforation is difficult with only one Q switch pulse, in terms of the physical properties of the green sheet GS and the characteristics of the laser beam LB, the process-track-change may be done after two or more times of processing is performed under the single circular track.

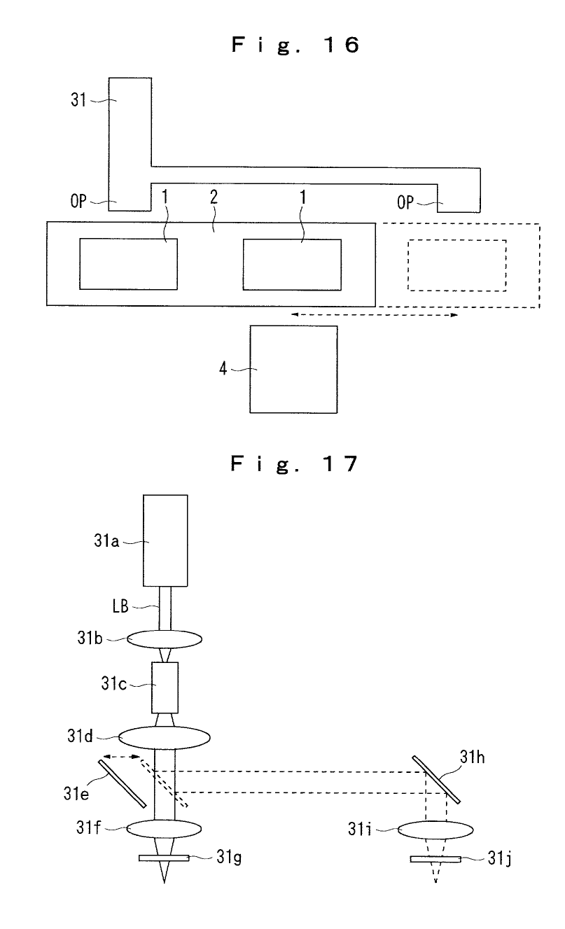

Further, in the first embodiment described above, the method is adopted in which the circular track is shifted by the predetermined pitch by allowing the drum 1 to travel the predetermined distance in its centerline direction every time immediately before the drum 1 has been rotated in the complete circle; however, if the process track is formed spirally on the periphery of the drum 1, a desired through hole matrix can be formed on the green sheet GS without allowing the drum 1 to travel in its centerline direction every time immediately before it has been rotated in a complete circle. Specifically, as shown in FIGS. 15(A) and 15(B), if the irradiation of laser beam LB is performed toward the green sheet GS intermittently while rotating the drum 1 at a predetermined rotational speed by the motor 6 and allowing it to travel in its centerline direction at a predetermined speed by the linear motor 8, a through hole matrix can be formed on the green sheet GS attached to the periphery of the drum 1 under the spiral track. In such a case, the direction of the green sheet GS attached to the periphery of the drum may be such that its side on the drum's edge side is parallel to the drum's edge or its side on the drum's edge side is parallel to the spiral process track.

In the first embodiment described above, the matrix of through holes SH is formed on the green sheet GS; however, a matrix of concave portions can also be formed on the green sheet GS if the energy of the laser beam irradiation is lowered. In addition, through holes or concave portions in the form other than a circle can also be formed on the green sheet GS if the shape of the laser beam LB irradiation is changed using a mask etc.

FIGS. 16 to 18 show a second embodiment of the present invention.

Referring to FIG. 16, there is shown a schematic view of a configuration of a processing apparatus which is the second embodiment. In FIG. 16, reference numeral 1 denotes two drums the periphery of which the green sheet can be detached from and attached to and numeral 2 denotes the translatable table on which the above two drums 1 are arranged. The table 2 is movable in such a manner that when one drum 1 is in either of the two processing positions (both end portions of the figure), the other drum 1 is in the non-processing position (in the middle of the figure). Numeral 31 denotes a dual output system laser beam irradiation machine having two output ends OP which are arranged in a position corresponding to the two processing positions so that they can irradiate the periphery of the drum 1 in any one of the two processing positions with the laser beam. Numeral 4 denotes the sheet attaching/detaching machine, which are arranged in a position corresponding to the above non-processing position so that it can detach the processed green sheets from the periphery of the drum 1 in the processing position and attach another unprocessed green sheets on it.

This processing apparatus has it configuration as the apparatus shown in the first embodiment, except for the configuration of the laser beam irradiation machine 31 and the number and arrangement of the sheet attaching/detaching machine 4. For the parts having it configuration as those of the apparatus shown in the first embodiment, it reference numerals are quoted and their descriptions are omitted.

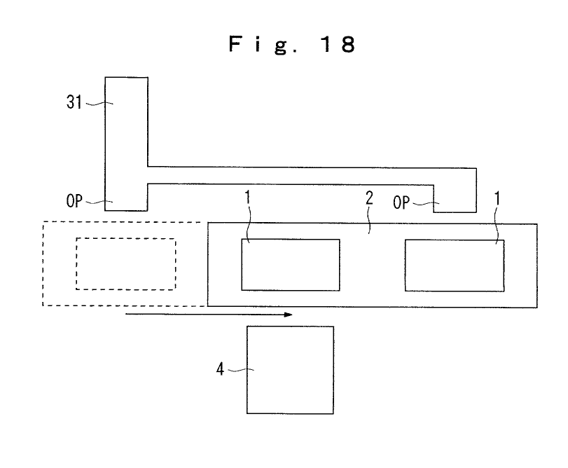

The laser beam irradiation machine 31 includes a laser oscillator 31a, a condenser lens 31b, a homogenizer 31c, a relay lens 31d, a movable output end changeover mirror 31e, a movable-mirror driving source (not shown in the figure), a first objective lens 31f, a first shielding plate 31g, a mirror 31h, a second objective lens 31i, and a first shielding plate 31j, as shown in FIG. 17. Of the two output ends OP described above, one indicates the first objective lens 31f and the first shielding plate 31g and the other the mirror 31h, the second objective lens 31i and a first shielding plate 31j.

Preferably the laser oscillator 31a consists of YAG laser oscillator such as CW-Q oscillation and normal pulse oscillation laser which oscillates fundamental wave or higher harmonic wave; however, other laser oscillators such as CO₂ laser and excimer laser can also be used. When the movable mirror 31e is in the position shown by the solid line in FIG. 17, the laser beam LB outgone from the laser oscillator 31a enters the homogenizer 31c via the condenser lens 31b, and the homogeneous laser beam LB outgone from the homogenizer 31c goes through the relay lens 31d and the first objective lens 31f and reaches the first shielding plate 31g placed thereunder. And when the movable mirror 31e is in the position shown by the broken line in FIG. 17, the laser beam LB outgone from the laser oscillator 31a enters the homogenizer 31c via the condenser lens 31b, and the homogeneous laser beam LB outgone from the homogenizer 31c enters the movable mirror 31e via the relay lens 31d and is reflected by the mirror 31e, and the reflected laser beam LB is further reflected by the mirror 31h, goes through the second objective lens 31i and reaches the second shielding plate 31j placed thereunder.

This first shielding plate 31g and the second shielding plate 31j accept a penetration of the laser beam, in addition, they serve to prevent the first and second objective lenses 31f and 31i from being contaminated with process dust produced when irradiating the green sheet with laser beam LB. As the first and second shielding plates 31g and 31j, those obtained by forming beam passing holes on a laser beam non-transmitting plate such as metal plate, laser beam transmitting plates such as glass plate, those obtained by forming a laser beam transmitting portion on a laser beam non-transmitting plate, and those obtained by stacking the above plates can be used properly.

The laser beam LB having reached the first shielding plate 31g via the first objective lens 31f penetrates the first shielding plate 31g and irradiates the green sheet GS in a prescribed form, for example, in the form of a circle. On the other hand, the laser beam LB having reached the second shielding plate 31j via the second objective lens 31i penetrates the second shielding plate 31j and irradiates the green sheet GS in a prescribed form, for example, in the form of a circle. The position of the green sheet GS irradiated with the laser beam LB is on the centerline of the drum 1 (refer to the alternate long and short dash line of FIG. 13), as seen from the side, and the centerline of the laser beam LB irradiating on the above position corresponds to the normal line from the center of the irradiated position of the drum 1.

In the following, a method of forming a matrix of through holes SH on the green sheet GS using the above described apparatus will be described.

When none of the two drums 1 have the green sheet GS attached thereon, first the table 2 is made to travel in such a manner as to allow one of the drums 1 to face one of the sheet attaching/detaching machines 4 (refer to FIG. 16), then the operation of attaching three unprocessed green sheets GS on the periphery of the drum 1 is performed using the above sheet attaching/detaching machine 4. This sheet attaching procedure is it as that of the first embodiment described above.

After three green sheets GS are attached to the periphery of one drum 1, the table 2 is made to travel so that the drum 1 having the green sheet GS attached thereon faces one of the output ends OP of the laser beam irradiation machine 31 (refer to FIG. 18), and the green sheet GS attached to the periphery of the drum 1 is subjected to processing with laser beam LB outgone from the above output end OP of the laser beam irradiation machine 31. This sheet processing procedure is it as that of the first embodiment described above.

While the green sheets GS attached to the periphery of one drum 1 are being subjected to processing of forming the through hole matrix, the operation of attaching three unprocessed green sheets GS on the periphery of the other drum 1 is performed with the sheet attaching/detaching machine 4, making use of this processing time. This sheet attaching procedure is it as that of the first embodiment described above.

After completion of the predetermined processing on the green sheets GS attached to the periphery of one drum 1, the table 2 is made to travel so that the other drum 1 having the unprocessed green sheets GS attached thereon faces the other output end OP of the laser beam irradiation machine 31 (refer to FIG. 16), and the processes are performed on the green sheets GS attached to the periphery of the drum 1 with the laser beam LB outgone from the other output end OP of the laser beam irradiation machine 31. This sheet processing procedure is it as that of the first embodiment described above.

While the green sheets GS attached to the periphery of the other drum 1 are being subjected to processing of forming the through hole matrix, the three processed green sheets GS are detached from the periphery of the above drum 1, on which the processing has been already completed, and the operation of attaching another three unprocessed green sheets GS on the periphery of it drum 1 is performed, with the sheet attaching/detaching machine 4, making use of the processing time. This sheet attaching/detaching procedure is it as that of the first embodiment described above.

As described above, according to the processing apparatus and processing method of the second embodiment, while performing the predetermined processing (formation of the through hole matrix) by exposing the three green sheets GS attached to the periphery of one drum 1 to the laser beam LB intermittently while rotating the drum 1 and allowing it to travel in the drum centerline direction, another operations of detaching the three processed green sheets from the periphery of the other drum 1 and attaching another three unprocessed green sheets GS on it can be performed. In other words, the predetermined processing is never stopped due to the operations of attaching/detaching sheets from/on the drum's periphery and can be performed continuously; as a result, the processing apparatus and processing method offer the advantages of greatly reducing the time required for the predetermined processing of the green sheet GS and improving the efficiency of part manufacturing, in addition, of greatly contributing to the reduction in unit cost of the manufactured part.

In terms of the drum 1 which is involved in the predetermined processing, since the formation of the through hole matrix on each of the three green sheets GS attached to the periphery of the drum can be performed without stopping the rotation of the drum 1, it is possible to form on the order of 1,000 to 10,000 through holes SH on the green sheet per second. Thus, the processing apparatus and processing method of the second embodiment offers the advantage of greatly reducing the time required for the formation of a desired through hole matrix on the green sheet GS, compared with the method currently in use.

Further, in terms of the drum 1 from and on which green sheets are detached and attached, the unprocessed green sheets GS can be attached to the periphery of the drum 1 and the processed green sheet GS can be detached from it in a state where they are adapted to the curvature of the periphery. Thus, the processing apparatus and processing method of the second embodiment offers the advantage of performing the operations of attaching/detaching sheets from/on the periphery of the drum 1 more efficiently and properly.

By the way, in the second embodiment described above, three green sheets GS are attached to the periphery of the drum 1; however, in cases where two or less green sheet(s) GS or four or more green sheets GS are attached to it, it processing and it sheet attaching/detaching operations as described above can be performed.

Further, in the second embodiment described above, three green sheets GS are attached to the periphery of the drum 1 in such a manner as to leave spaces between the two adjacent green sheets and one space is used as part of the process-track-change-area; however, if the area equivalent to the above space is ensured on the green sheet side, such the space is not always needed, and it processing as described above can be performed even when attaching the green sheet with no spaces therebetween.

In the second embodiment described above, through holes SH are formed on the green sheet GS with one Q switch pulse; however, in cases where perforation is difficult with only one Q switch pulse, in terms of the physical properties of the green sheet GS and the characteristics of the laser beam LB, the process-track-change may be done after two or more times of processing is performed under the single circular track.

Further, in the second embodiment described above, the method is adopted in which the circular track is shifted by the predetermined pitch by allowing the drum 1 to travel the predetermined distance in its centerline direction every time immediately before the drum 1 has been rotated in the complete circle; however, if the process track is formed spirally on the periphery of the drum 1 in the same manner as described in the first embodiment, a desired through hole matrix can be formed on the green sheet GS without allowing the drum 1 to travel in its centerline direction every time immediately before it has been rotated in a complete circle.

In the second embodiment described above, the matrix of through holes SH is formed on the green sheet GS; however, a matrix of concave portions can also be formed on the green sheet GS if the energy of the laser beam irradiation is lowered. In addition, through holes or concave portions in the form other than a circle can also be formed on the green sheet GS if the shape of the laser beam irradiation is changed using a mask etc.

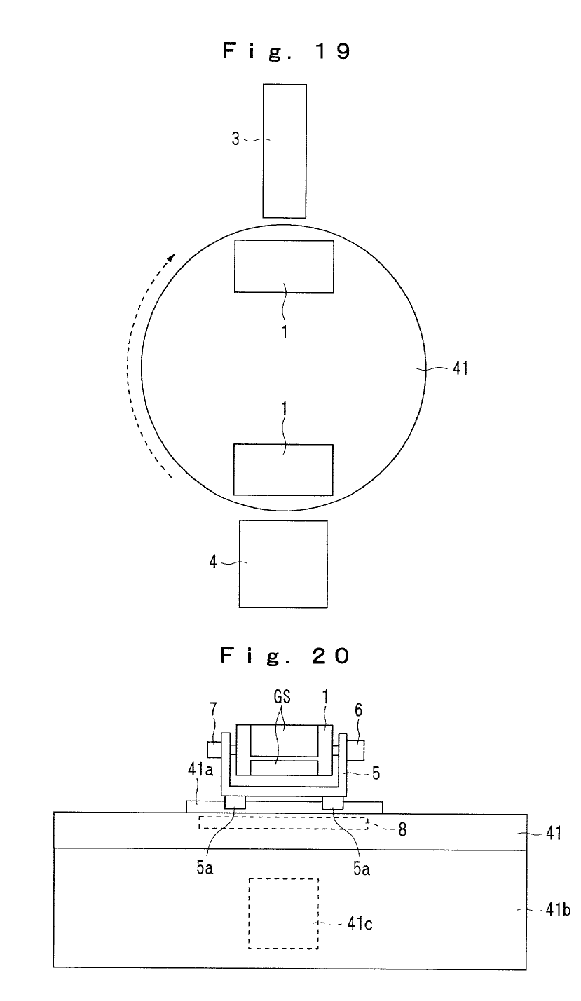

FIGS. 19 and 20 show a third embodiment of the present invention.

Referring to FIG. 19, there is shown a schematic view of a configuration of a processing apparatus which is the third embodiment. In FIG. 19, reference numeral 1 denotes two drums the periphery of which the green sheet can be detached from and attached to and numeral 41 denotes a rotationally movable table on which the above two drums 1 are arranged. The table 41 is movable in such a manner that when one drum 1 is in the processing positions (the upper side position of the figure), the other drum is in the non-processing positions (the lower side position of the figure). Numeral 3 denotes the laser beam irradiation machine, which is arranged in a position corresponding to the processing position so that it can irradiate the periphery of the drum 1 in the processing position with laser beam. Numeral 4 denotes the sheet attaching/detaching machine, which is arranged in a position corresponding to the above processing position so that it can detach the processed green sheets from the periphery of the drum 1 in the processing position and attach another unprocessed green sheets on it.

This processing apparatus has it configuration as the apparatus shown in the first embodiment, except for the configuration of the table 41 and the number and arrangement of the sheet attaching/detaching machine 4. For the parts having it configuration as those of the apparatus shown in the first embodiment, it reference numerals are quoted and their descriptions are omitted.

Each of the drums 1 is supported by a support stand 5 at its drum shaft 1b in a rotatable manner, as shown in FIG. 20, and they are arranged on the table 41 in such a manner that they are symmetric with respect to the center of the table 41. Each supporting stand 5 has rail guides 5a provided on the lower surface of its bottom in such a manner as to allow them to mesh with a rail 41a provided on the table 41, and between the supporting stand 5 and the table 41 provided is a linear motor 8, 8 which allows the supporting stands 5 to travel along a straight line individually. The table 41 is supported by a base 41b provided on its lower surface, and the base 41b is provided with a motor 41c for moving the table 41 rotationally.

In the following, a method of forming a matrix of through holes SH on the green sheet GS using the above described apparatus will be described.

When none of the two drums 1 have the green sheet GS attached thereon, first the table 41 is made to travel in such a manner as to allow one of the drums 1 to face one of the sheet attaching/detaching machines 4 (refer to FIG. 19), then the operation of attaching three unprocessed green sheets GS on the periphery of the drum 1 is performed using the above sheet attaching/detaching machine 4. This sheet attaching procedure is it as that of the first embodiment described above.

After three green sheets GS are attached to the periphery of one drum 1, the table 41 is made to travel so that the drum 1 having the green sheet GS attached thereon faces the laser beam irradiation machine 3 (refer to FIG. 19), and the green sheet GS attached to the periphery of the drum 1 is subjected to processing with laser beam LB outgone from the above laser beam irradiation machine 3. This sheet processing procedure is it as that of the first embodiment described above.

While the green sheets GS attached to the periphery of one drum 1 are being subjected to processing of forming the through hole matrix, the operation of attaching three unprocessed green sheets GS on the periphery of the other drum 1 is performed with the sheet attaching/detaching machine 4, making use of this processing time. This sheet attaching procedure is it as that of the first embodiment described above.

After completion of the predetermined processing on the green sheet GS attached to one drum 1, the table 41 is made to travel so that the other drum 1 having the unprocessed green sheets GS attached thereon faces the laser beam irradiation machine 3 (refer to FIG. 19), and the processes are performed on the green sheets GS attached to the periphery of the drum 1 with the laser beam LB outgone from the laser beam irradiation machine 3. This sheet processing procedure is it as that of the first embodiment described above.

While the green sheets GS attached to the periphery of the other drum 1 are being subjected to processing of forming the through hole matrix, the three processed green sheets GS are detached from the periphery of the above drum 1, on which the processing has been already completed, and the operation of attaching another three unprocessed green sheets GS on the periphery of it drum 1 is performed, with the sheet attaching/detaching machine 4, making use of the processing time. This sheet attaching/detaching procedure is it as that of the first embodiment described above.

As described above, according to the processing apparatus and processing method of the third embodiment, while performing the predetermined processing (formation of the through hole matrix) by exposing the three green sheets GS attached to the periphery of one drum to the laser beam LB intermittently while rotating the drum 1 and allowing it to travel in the drum centerline direction, another operations of detaching the three processed green sheets from the periphery of the other drum 1 and attaching another three unprocessed green sheets GS on it can be performed. In other words, the predetermined processing is never stopped due to the operations of attaching/detaching sheets from/on the drum's periphery and can be performed continuously; as a result, the processing apparatus and processing method offer the advantages of greatly reducing the time required for the predetermined processing of the green sheet GS and improving the efficiency of part manufacturing, in addition, of greatly contributing to the reduction in unit cost of the manufactured part.

In terms of the drum 1 which is involved in the predetermined processing, since the formation of the through hole matrix on each of the three green sheets GS attached to the periphery of the drum can be performed without stopping the rotation of the drum 1, it is possible to form on the order of 1,000 to 10,000 through holes SH on the green sheet per second. Thus, the processing apparatus and processing method of the third embodiment offers the advantage of greatly reducing the time required for the formation of a desired through hole matrix on the green sheet GS, compared with the method currently in use.

Further, in terms of the drum 1 from and on which green sheets are detached and attached, the unprocessed green sheets GS can be attached to the periphery of the drum 1 and the processed green sheet GS can be detached from it in a state where they are adapted to the curvature of the periphery. Thus, the processing apparatus and processing method of the third embodiment offers the advantage of performing the operations of attaching/detaching sheets from/on the periphery of the drum 1 more efficiently and properly.

By the way, in the third embodiment described above, three green sheets GS are attached to the periphery of the drum 1; however, in cases where two or less green sheet(s) GS or four or more green sheets GS are attached to it, it processing and it sheet detaching/attaching operations as described above can be performed.

Further, in the third embodiment described above, three green sheets GS are attached to the periphery of the drum 1 in such a manner as to leave spaces between the two adjacent green sheets and one space is used as part of the process-track-change-area; however, if the area equivalent to the above space is ensured on the green sheet side, such the space is not always needed, and it processing as described above can be performed even when attaching the green sheet with no spaces therebetween.

In the third embodiment described above, through holes SH are formed on the green sheet GS with one Q switch pulse; however, in cases where perforation is difficult with only one Q switch pulse, in terms of the physical properties of the green sheet GS and the characteristics of the laser beam LB, the process-track-change may be done after two or more times of processing is performed under the single circular track.

Further, in the third embodiment described above, the method is adopted in which the circular track is shifted by the predetermined pitch by allowing the drum 1 to travel the predetermined distance in its centerline direction every time immediately before the drum 1 has been rotated in the complete circle; however, if the process track is formed spirally on the periphery of the drum 1 in the same manner as described in the first embodiment, a desired through hole matrix can be formed on the green sheet GS without allowing the drum 1 to travel in its centerline direction every time immediately before it has been rotated in a complete circle.

In the third embodiment described above, the matrix of through holes SH is formed on the green sheet GS; however, a matrix of concave portions can also be formed on the green sheet GS if the energy of the laser beam irradiation is lowered. In addition, through holes or concave portions in the form other than a circle can also be formed on the green sheet GS if the shape of the laser beam irradiation is changed using a mask etc.

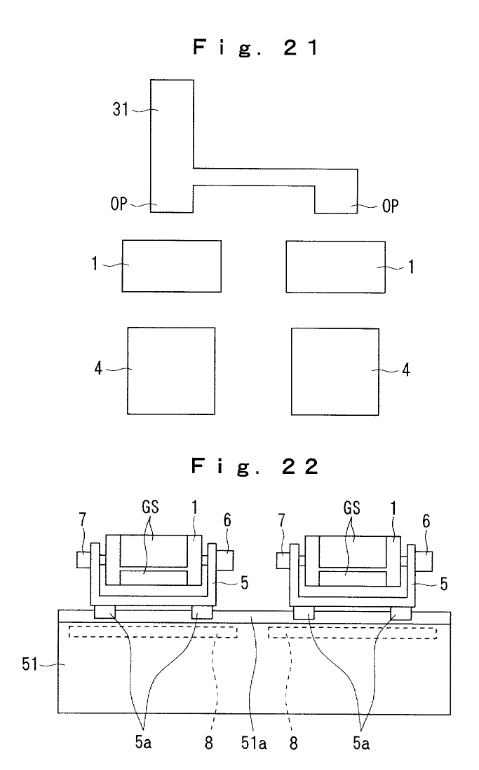

FIGS. 21 and 22 show a fourth embodiment of the present invention.

Referring to FIG. 21, there is shown a schematic view of a configuration of a processing apparatus which is the fourth embodiment. In FIG. 21, reference numeral 1 denotes two drums the periphery of which the green sheet can be detached from and attached to. Numeral 31 denotes the dual output system laser beam irradiation machine having two output ends OP each of which is arranged in a position corresponding to the two drums 1 so that they can irradiate the periphery of one of the drums 1 with the laser beam. Numeral 4 denotes two sheet attaching/detaching machines, which are arranged in a position corresponding to the two processing positions, respectively, so that they can detach the processed green sheets from the periphery of the drums in the two processing positions and attach another unprocessed green sheets on it.

This processing apparatus has it configuration as the apparatus shown in the first embodiment, except for the configuration of the laser beam irradiation machine 31 and the arrangement of the drums. For the parts having it configuration as those of the apparatus shown in the first embodiment, it reference numerals are quoted and their descriptions are omitted. And for the configuration of the laser beam irradiation machine 31, it is it as that of the apparatus shown in the second embodiment, accordingly, it reference numerals are quoted and their descriptions are omitted.

Each of the drums 1 is arranged on a base 51 in such a manner that it is supported by a support stand 5 at its drum shaft 1b in a rotatable manner, as shown in FIG. 22. Each supporting stand 5 has rail guides 5a provided on the lower surface of its bottom in such a manner as to allow them to mesh with a rail 51a provided on the base 51, and between the supporting stand 5 and the base 51 provided is a linear motor 8, 8 which allows the supporting stands 5 to travel along a straight line individually.

In the following, a method of forming a matrix of through holes SH on the green sheet GS using the above described apparatus will be described.

When none of the two drums 1 have the green sheet GS attached thereon, first the operation of attaching three unprocessed green sheets GS on the periphery of one of the two drums 1 is performed using one of the above sheet attaching/detaching machines 4. This sheet attaching procedure is it as that of the first embodiment described above.

After three green sheets GS are attached to the periphery of one drum 1, the green sheets GS attached to the periphery of the above drum 1 is subjected to processing with laser beam LB outgone from one of the output ends OP of the laser beam irradiation machine 31. This sheet processing procedure is it as that of the first embodiment described above.

While the green sheets GS attached to the periphery of one drum 1 are being subjected to processing of forming the through hole matrix, the operation of attaching three unprocessed green sheets GS on the periphery of other drum 1 is performed with the other sheet attaching/detaching machine 4, making use of this processing time. This sheet attaching procedure is it as th at of the first embodiment described above.

After completion of the predetermined processing on the green sheets GS attached to the periphery of one drum 1, the process is performed on the green sheets GS attached to the periphery of the other drum 1 with the laser beam LB outgone from the other output end OP of the laser beam irradiation machine 31. This sheet processing procedure is it as that of the first embodiment described above.

While the green sheets GS attached to the periphery of the other drum 1 are being subjected to processing of forming the through hole matrix, the three processed green sheets GS are detached from the periphery of the above drum 1, on which the processing has been already completed, and the operation of attaching another three unprocessed green sheets GS on the periphery of it drum 1 is performed, with one of the sheet attaching/detaching machines 4, making use of the processing time. This sheet attaching/detaching procedure is it as that of the first embodiment described above.

As described above, according to the processing apparatus and processing method of the fourth embodiment, while performing the predetermined processing (formation of the through hole matrix) by exposing the three green sheets GS attached to the periphery of one drum to the laser beam LB intermittently while rotating the drum 1 and allowing it to travel in the drum centerline direction, another operations of detaching the three processed green sheets from the periphery of the other drum 1 and attaching another three unprocessed green sheets GS on it can be performed. In other words, the predetermined processing is never stopped due to the operations of attaching/detaching sheets from/on the drum's periphery and can be performed continuously; as a result, the processing apparatus and processing method offer the advantages of greatly reducing the time required for the predetermined processing of the green sheet GS and improving the efficiency of part manufacturing, in addition, of greatly contributing to the reduction in unit cost of the manufactured part.

In terms of the drum 1 which is involved in the predetermined processing, since the formation of the through hole matrix on each of the three green sheets GS attached to the periphery of the drum can be performed without stopping the rotation of the drum, it is possible to form on the order of 1,000 to 10,000 through holes SH on the green sheet per second. Thus, the processing apparatus and processing method of the fourth embodiment offers the advantage of greatly reducing the time required for the formation of a desired through hole matrix on the green sheet GS, compared with the method currently in use.

Further, in terms of the drum 1 from and on which green sheets are detached and attached, the unprocessed green sheets GS can be attached to the periphery of the drum 1 and the processed green sheet GS can be detached from it in a state where they are adapted to the curvature of the periphery. Thus, the processing apparatus and processing method of the fourth embodiment offers the advantage of performing the operations of attaching/detaching sheets from/on the periphery of the drum 1 more efficiently and properly.

By the way, in the fourth embodiment described above, three green sheets GS are attached to the periphery of the drum 1; however, in cases where two or less green sheet(s) GS or four or more green sheets GS are attached to it, it processing and it sheet attaching/detaching operations as described above can be performed.

Further, in the fourth embodiment described above, three green sheets GS are attached to the periphery of the drum 1 in such a manner as to leave spaces between the two adjacent green sheets and one space is used as part of the process-track-change-area; however, if the area equivalent to the above space is ensured on the green sheet side, such the space is not always needed, and it processing as described above can be performed even when attaching the green sheet with no spaces therebetween.

In the fourth embodiment described above, through holes SH are formed on the green sheet GS with one Q switch pulse; however, in cases where perforation is difficult with only one Q switch pulse, in terms of the physical properties of the green sheet GS and the characteristics of the laser beam LB, the process-track-change may be done after two or more times of processing is performed under a single circular track.

Further, in the fourth embodiment described above, the method is adopted in which the circular track is shifted by the predetermined pitch by allowing the drum 1 to travel the predetermined distance in its centerline direction every time immediately before the drum 1 has been rotated in the complete circle; however, if the process track is formed spirally on the periphery of the drum 1 in the same manner as described in the first embodiment, a desired through hole matrix can be formed on the green sheet GS without allowing the drum 1 to travel in its centerline direction every time immediately before it has been rotated in a complete circle.

In the fourth embodiment described above, the matrix of through holes SH is formed on the green sheet GS; however, a matrix of concave portions can also be formed on the green sheet GS if the energy of the laser beam irradiation is lowered. In addition, through holes or concave portions in the form other than a circle can also be formed on the green sheet GS if the shape of the laser beam irradiation is changed using a mask etc.

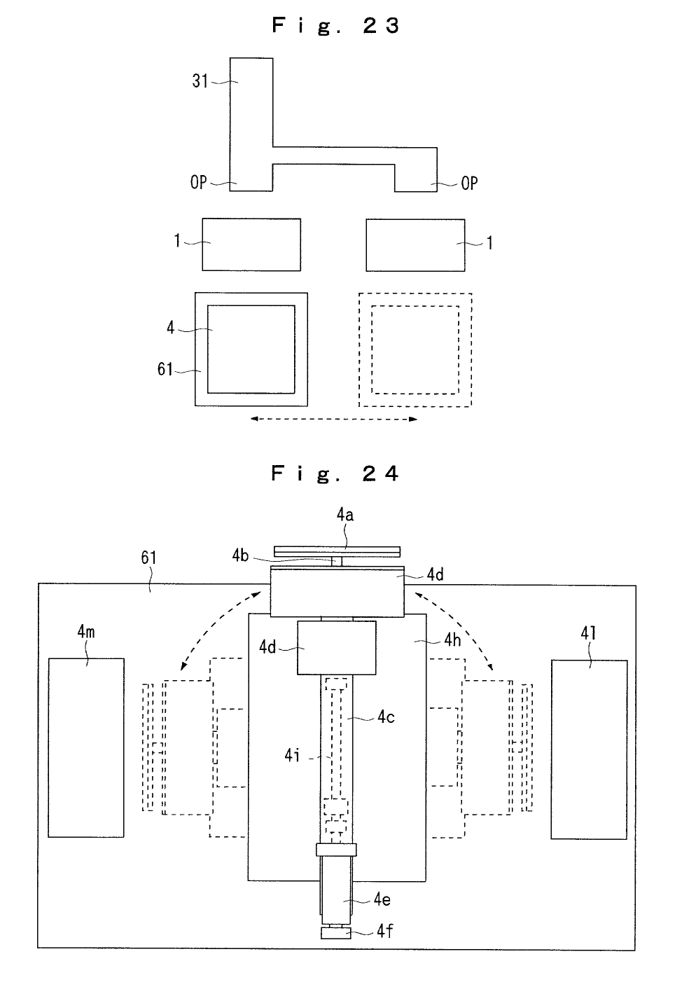

FIGS. 23 to 25 show a fifth embodiment of the present invention.

Referring to FIG. 23, there is shown a schematic view of a configuration of a processing apparatus which is the fifth embodiment. In FIG. 23, reference numeral 1 denotes two drums the periphery of which the green sheet can be detached from and attached to. Numeral 31 denotes the dual output system laser beam irradiation machine having two output ends OP each of which is arranged in a position corresponding to the two drums 1 so that they can irradiate the periphery of one of the drums 1 with the laser beam. Numeral 4 denotes one sheet attaching/detaching machine and numeral 61 a translatable table on which the sheet attaching/detaching machine 4 is arranged. The table 61 is movable in such a manner that the sheet attaching/detaching machine 4 faces either of the two drums 1.

This processing apparatus has it configuration as the apparatus shown in the first embodiment, except for the configuration of the laser beam irradiation machine 31, the arrangement of the drums, and the number and arrangement of the sheet attaching/detaching machine 4. For the parts having it configuration as those of the apparatus shown in the first embodiment, it reference numerals are quoted and their descriptions are omitted. And for the configuration of the laser beam irradiation machine 31, it is it as that of the apparatus shown in the second embodiment, accordingly, it reference numerals are quoted and their descriptions are omitted.

The sheet attaching/detaching machine 4 is arranged on the table 61, as shown in FIG. 24, and the table 61 is allowed to travel in the direction parallel to the drum's centerline by a linear driving mechanism (not shown in the figure).

In the following, a method of forming a matrix of through holes SH on a green sheet GS using the above described apparatus will be described.

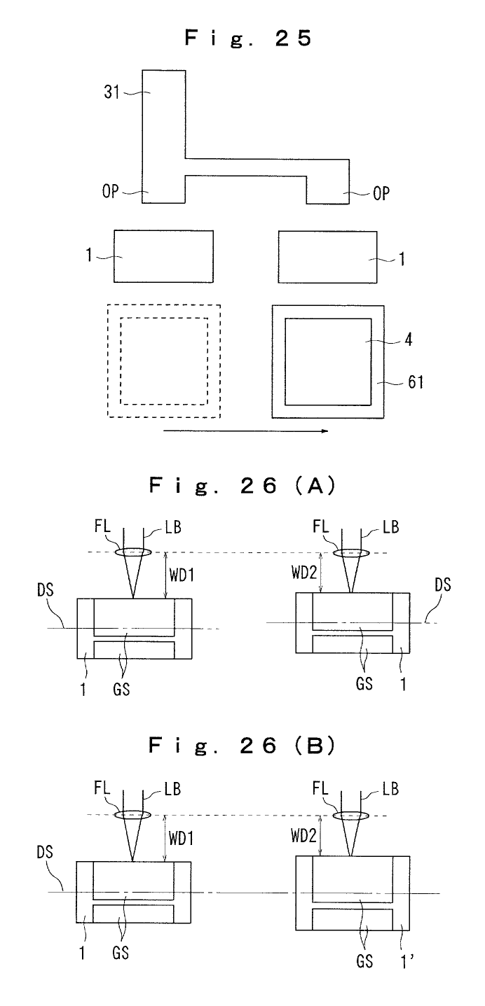

When none of the two drums 1 have the green sheet GS attached thereon, first the table 61 is made to travel in such a manner as to allow one of the drums 1 to face the sheet attaching/detaching machines 4 (refer to FIGS. 23 and 25), then the operation of attaching three unprocessed green sheets GS on the periphery of one drum 1 is performed using the above sheet attaching/detaching machine 4. This sheet attaching procedure is it as that of the first embodiment described above.

After three green sheets GS are attached to the periphery of one drum 1, the green sheets GS attached to the periphery of the above drum 1 is subjected to processing with laser beam LB outgone from one of the output ends OP of the laser beam irradiation machine 31. This sheet processing procedure is it as that of the first embodiment described above.

While the green sheets GS attached to the periphery of one drum 1 are being subjected to processing of forming the through hole matrix, the table 61 is made to travel in such a manner as to allow the sheet attaching/detaching machine 4 to face the other drum 1 (refer to FIGS. 23 and 25) and the operation of attaching three unprocessed green sheets on the above drum 1 is performed with the sheet attaching/detaching machine 4, making use of this processing time. This sheet attaching procedure is it as that of the first embodiment described above.

After completion of the predetermined processing on the green sheets GS attached to the periphery of one drum 1, the process is performed on the green sheets GS attached to the periphery of the other drum 1 with the laser beam LB outgone from the other output end OP of the laser beam irradiation machine 31. This sheet processing procedure is it as that of the first embodiment described above.

While the green sheets GS attached to the periphery of the other drum 1 are being subjected to processing of forming the through hole matrix, the table 61 is made to travel in such a manner as to allow the sheet attaching/detaching machine 4 to face the drum 1 (refer to FIGS. 23 and 25), on which the three processed green sheets GS are detached from the periphery of the drum 1 on which the processing has been already completed, and the operation of attaching another three unprocessed green sheets GS on the periphery of it drum 1 is performed, with the sheet attaching/detaching machines 4, making use of the processing time. This sheet attaching/detaching procedure is it as that of the first embodiment described above.

As described above, according to the processing apparatus and processing method of the fifth embodiment, while performing the predetermined processing (formation of the through hole matrix) by exposing the three green sheets GS attached to the periphery of one drum to the laser beam LB intermittently while rotating the drum 1 and allowing it to travel in the drum centerline direction, another operations of detaching the three processed green sheets from the periphery of the other drum 1 and attaching another three unprocessed green sheets GS on it can be performed In other words, the predetermined processing is never stopped due to the operations of attaching/detaching sheets from/on the drum's periphery and can be performed continuously; as a result, the processing apparatus and processing method offer the advantages of greatly reducing the time required for the predetermined processing of the green sheet GS and improving the efficiency of part manufacturing, in addition, of greatly contributing to the reduction in unit cost of the manufactured part.

In terms of the drum 1 which is involved in the predetermined processing, since the formation of the through hole matrix on each of the three green sheets GS attached to the periphery of the drum can be performed without stopping the rotation of the drum 1, it is possible to form on the order of 1,000 to 10,000 through holes SH on the green sheet per second. Thus, the processing apparatus and processing method of the fifth embodiment offers the advantage of greatly reducing the time required for the formation of a desired through hole matrix on the green sheet GS, compared with the method currently in use.

Further, in terms of the drum 1 from and on which green sheets are detached and attached, the unprocessed green sheets GS can be attached to the periphery of the drum 1 and the processed green sheet GS can be detached from it in a state where they are adapted to the curvature of the periphery. Thus, the processing apparatus and processing method of the fifth embodiment offers the advantage of performing the operations of attaching/detaching sheets from/on the periphery of the drum 1 more efficiently and properly.

By the way, in the fifth embodiment described above, three green sheets GS are attached to the periphery of the drum 1; however, in cases where two or less green sheet(s) GS or four or more green sheets GS are attached to it, it processing and it sheet attaching/detaching operations as described above can be performed.

Further, in the fifth embodiment described above, three green sheets GS are attached to the periphery of the drum 1 in such a manner as to leave spaces between the two adjacent green sheets and one space is used as part of the process-track-change-area; however, if the area equivalent to the above space is ensured on the green sheet side, such the space is not always needed, and it processing as described above can be performed even when attaching the green sheet with no spaces therebetween.

In the fifth embodiment described above, through holes SH are formed on the green sheet GS with one Q switch pulse; however, in cases where perforation is difficult with only one Q switch pulse, in terms of the physical properties of the green sheet GS and the characteristics of laser beam LB, the process-track-change may be done after two or more times of processing is performed under a single circular track.

Further, in the fifth embodiment described above, the method is adopted in which the circular track is shifted by the predetermined pitch by allowing the drum 1 to travel the predetermined distance in its centerline direction every time immediately before the drum 1 has been rotated in the complete circle; however, if the process track is formed spirally on the periphery of the drum 1 in the same manner as described in the first embodiment, a desired through hole matrix can be formed on the green sheet GS without allowing the drum 1 to travel in its centerline direction every time immediately before it has been rotated in a complete circle.

In the fifth embodiment described above, the matrix of through holes SH is formed on the green sheet GS; however, a matrix of concave portions can also be formed on the green sheet GS if the energy of the laser beam irradiation is lowered. In addition, through holes or concave portions in the form other than a circle can also be formed on the green sheet GS if the shape of the laser beam irradiation is changed using a mask etc..

In the first to fifth embodiments described above, the methods and apparatuses are shown in which the green sheet attached to the two different drums are subjected to it processing. However, if the two drums 1 are arranged in such a manner that their centerlines DS are staggered so that the intervals between their objective lens FL and the green sheet GS, WD1 and WD2, are different from each other, as shown in FIG. 26(A), the green sheet GS attached to one drum 1 and those of the other drum 1 can be subjected to processing different in size; for example, they can have through holes or concave portions different in size formed thereon. Alternatively, as shown in FIG. 26 (B), if two drums, drum 1 and drum 1′, different in diameter are used so that the intervals between their objective lens FL and the green sheet GS, WD1 and WD2, are different from each other, it processing can be performed. In either case, if the intervals WD1 and WD2 are fine-tuned by changing the position of the objective lenses FL in the optical axis direction, the processing sizes on the green sheet GS attached to the two drums 1, 1 or 1, 1′, for example, the sizes of through holes or concave portions can be controlled.

Besides, in the first to fifth embodiments described above, the methods and apparatuses are shown in which one of two drums is subjected to sheet processing while the other is subjected to sheet attaching/detaching. However, the methods and apparatuses may be such that at least one of three drums is subjected to sheet processing while the others are subjected to sheet attaching/detaching. It goes without saying that the processing apparatus may consist of the combination of two or more of the apparatuses shown in the first to fifth embodiments.

The preferred embodiments are illustrative and not restrictive. Since the scope of the present invention is defined solely by the appended claims, all variations that fall within the spirits of the claims are intended to be covered by the present invention.

1. A method of manufacturing a multilayer electronic part, comprising a step of subjecting a green sheet to a predetermined processing by irradiating the green sheet with a laser beam, said processing step is performed by:
using some of two or more drums, the periphery of which the green sheet can be attached to and detached from, as a processing-side drum and the rest thereof as a non-processing-side drum;
subjecting the green sheet attached to the periphery of the processing-side drum to the predetermined processing by irradiating it with the laser beam at least one beam irradiation means while allowing the processing-side drum to rotate about the drum's centerline as an axis, and travel in the direction of the drum's centerline; and
detaching a processed green sheet from the periphery of the non-processing-side drum and attaching an unprocessed green sheet on it with at least one sheet attaching/detaching means while subjecting the green sheet to the predetermined processing.

2. The method of manufacturing the multilayer electronic part according to claim 1, wherein said processing step is performed by placing two or more drums on a translatable table and allowing the table to travel in such a manner that when some of the two or more drums is in the processing position, the rest thereof is in the non-processing position.

3. The method of manufacturing the multilayer electronic part according to claim 2, wherein said processing step is performed by:
placing two drums on the translatable table and allowing the table to travel in such a manner that when one drum is in one processing position, the other drum is in any one of two non-processing positions;
subjecting the green sheet attached to the periphery of one drum in the one processing position to the predetermined processing by irradiating it with the laser beam from one beam irradiation means which is arranged in a position corresponding to the one processing position while allowing the drum to rotate about the drum's centerline as the axis and travel in the direction of the drum's centerline; and
detaching the processed green sheet from the periphery of the other drum in any one of the two non-processing positions and attaching the unprocessed green sheet to it with one of two sheet attaching/detaching means arranged in a position corresponding to the two non-processing positions while subjecting the green sheet attached to the periphery of one drum in the processing position to the predetermined processing.

4. The method of manufacturing the multilayer electronic part according to claim 2, wherein said processing step is performed by:
placing two drums on the translatable table and allowing the table to travel in such a manner that when one drum is in one non-processing position, the other drum is in any one of two processing positions;
subjecting the green sheet attached to the periphery of one drum in any one of the two processing positions to the predetermined processing by irradiating it with the laser beam from one of two output ends of the beam irradiation means having two output systems of which the two output ends are arranged in a position corresponding to the two processing position while allowing the drum to rotate about the drum's centerline as the axis and travel in the direction of the drum's centerline; and
detaching the processed green sheet from the periphery of the other drum in the one non-processing position and attaching the unprocessed green sheet to it with one sheet attaching/detaching means arranged in a position corresponding to the one non-processing position while subjecting the green sheet attached to the periphery of one drum in the processing position to the predetermined processing.

5. The method of manufacturing the multilayer electronic part according to claim 1, wherein said processing step is performed by
placing two or more drums on a rotationally movable table and allowing the table to travel in such a manner that when some of the two or more drums is in the processing position, the rest thereof is in the non-processing position.

6. The method of manufacturing the multilayer electronic part according to claim 5, wherein said processing step is performed by:
placing two drums on the rotationally movable table and allowing the table to travel in such a manner that when one drum is in one processing position, the other drum is in one non-processing position;
subjecting the green sheet attached to the periphery of one drum in the one processing position to the predetermined processing by irradiating it with the laser beam from one beam irradiation means which is arranged in a position corresponding to the one processing position while allowing the drum to rotate about the drum's centerline as the axis and travel in the direction of the drum's centerline; and
detaching the processed green sheet from the periphery of the other drum in one non-processing position and attaching the unprocessed green sheet to it with one sheet attaching/detaching means arranged in a position corresponding to the one non-processing position while subjecting the green sheet attached to the periphery of one drum in the processing position to the predetermined processing.

7. The method of manufacturing the multilayer electronic part according to claim 1, wherein said processing step is performed by:
subjecting the green sheet attached to the periphery of the processing-side drum to the predetermined processing by irradiating it with the laser beam from at least one output end of the beam irradiation means having two or more output systems of which the output ends are arranged in a position corresponding to the two or more drums while allowing the processing-side drum to rotate about the drum's centerline as the axis and travel in the direction of the drum's centerline; and
detaching the processed green sheet from the periphery of the non-processing-side drum and attaching the unprocessed green sheet to it with the sheet attaching/detaching means arranged in a position corresponding to the two or more drums while subjecting the green sheet attached to the periphery of the processing-side drum to the predetermined processing.

8. The method of manufacturing the multilayer electronic part according to claim 1, wherein said processing step is performed by:
subjecting the green sheet attached to the periphery of the processing-side drum to the predetermined processing by irradiating it with laser beam from at least one output end of the beam irradiation means having two or more output systems of which the output ends are arranged in a position corresponding to the two or more drums while allowing the processing-side drum to rotate about the drum's centerline as the axis and travel in the direction of the drum's centerline; and
detaching the processed green sheet from the periphery of the non-processing-side drum and attaching the unprocessed green sheet to it with at least one sheet attaching/detaching means arranged on a translatable table by allowing the table to travel to the position in which the sheet attaching/detaching means corresponds to the non-processing side drum while subjecting the green sheet attached to the periphery of the processing-side drum to the predetermined processing.

9. An apparatus for manufacturing a multilayer electronic part, comprising an apparatus for subjecting a green sheet to a predetermined processing by irradiating it with a laser beam, said processing apparatus comprising:
two or more drums the periphery of which the green sheet can be detached from and attached to, some of the two or more drums being used as a processing-side drum and the rest thereof being used as a non-processing-side drum;
a drum driving means allowing the processing-side drum to rotate about the drum's centerline as an axis and travel in the direction of the drum's centerline;
at least one beam irradiation means capable of irradiating the laser beam toward the periphery of the processing-side drum;
at least one sheet attaching/detaching means capable of attaching the green sheet to and detaching it from the periphery of the non-processing-side drum;
a process control means for controlling the drum driving means and beam irradiation means so that the beam irradiation means can irradiate the green sheet attached to the periphery of the processing-side drum with the laser beam while allowing the processing-side drum to rotate about the drum's centerline as the axis and travel in the direction of the drum's centerline; and
a sheet attaching/detaching control means for controlling the sheet attaching/detaching means so that, while the green sheet on the periphery of the processing-side drum are subjected to processing, the sheet attaching/detaching means can detach a processed green sheet from the periphery of the non-processing-side drum and attach an unprocessed green sheet to it.

10. The apparatus for manufacturing the multilayer electronic part according to claim 9, said processing apparatus further comprising:
a translatable table on which the drums are arranged; and
a table driving means for providing the table with a predetermined linear motion.

11. The apparatus for manufacturing the multilayer electronic part according to claim 10, wherein:
the translatable table has two drums arranged thereon;
the table driving means allows the table to travel in such a manner that when one drum is in one processing position, the other drum is in any one of two non-processing positions;
the laser beam irradiation means is one, the laser beam irradiation means is arranged in a position corresponding to the one processing position so as to irradiate the laser beam toward the periphery of one drum in the one processing position;
the sheet attaching/detaching means is two, the two sheet attaching/detaching means are respectively arranged in a position corresponding to the two non-processing positions so as to detach the processed green sheet from the periphery of the drum in any one of the two non-processing positions and attach the unprocessed green sheet to it;
the process control means controls the drum driving means, the laser beam irradiation means and the table driving means so that one drum is moved to the one processing position, and the green sheet attached to the periphery of the drum can be irradiated with the laser beam from the laser beam irradiation means while allowing the drum to rotate about the drum's centerline as the axis and travel in the drum's centerline direction; and
the sheet attaching/detaching control means controls the sheet attaching/detaching means so that, while subjecting the green sheet on the periphery of one drum to processing, the processed green sheet can be detached from the periphery of the other drum in any one of the two non-processing positions and the unprocessed green sheet can be attached to it with one of the two sheet attaching/detaching means.

12. The apparatus for manufacturing the multilayer electronic part according to claim 10, wherein:
the translatable table has two drums arranged thereon;
the table driving means allows the table to travel in such a manner that when one drum is in one non-processing position, the other drum is in any one of two processing positions;
the laser beam irradiation means has two output systems and their output ends are respectively arranged in a position corresponding to the two processing positions so as to irradiate the laser beam toward the periphery of one drum in any one of the two processing positions;
the sheet attaching/detaching means is one, the sheet attaching/detaching means is arranged in a position corresponding to the one non-processing position so as to detach the processed green sheet from the periphery of the drum in the one non-processing position and attach the unprocessed green sheet to it;
the process control means controls the drum driving means, the laser beam irradiation means and the table driving means so that one drum is moved to any one of the two processing positions, and the green sheet attached to the periphery of the drum can be irradiated with the laser beam from one of the output ends of the laser beam irradiation means while allowing the drum to rotate about the drum's centerline as the axis and travel in the drum's centerline direction; and
the sheet attaching/detaching control means controls the sheet attaching/detaching means so that, while subjecting the green sheet on the periphery of one drum to processing, the processed green sheet can be detached from the periphery of the other drum in the one non-processing position and the unprocessed green sheet can be attached to it with the sheet attaching/detaching means.

13. The apparatus for manufacturing the multilayer electronic part according to claim 9, said processing apparatus further comprising:
a rotationally movable table on which two or more drums are arranged; and
a table driving means for providing the table with a predetermined rotational motion.

14. The apparatus for manufacturing the multilayer electronic part according to claim 13, wherein:
the rotationally movable table has two drums arranged thereon;
the table driving means allows the table to travel in such a manner that when one drum is in one processing position, the other drum is in one non-processing position;
the laser beam irradiation means is one, the laser beam irradiation means is arranged in a position corresponding to the one processing position so as to irradiate the laser beam toward the periphery of one drum in the one processing position;
the sheet attaching/detaching means is one, the sheet attaching/detaching means is arranged in a position corresponding to the one non-processing position so as to detach the processed green sheet from the periphery of the drum in the one non-processing position and attach the unprocessed green sheet to it;
the process control means controls the drum driving means, the laser beam irradiation means and the table driving means so that one drum is moved to the one processing position, and the green sheet attached to the periphery of the drum can be irradiated with the laser beam from the laser beam irradiation means while allowing the drum to rotate about the drum's centerline as the axis and travel in the drum's centerline direction; and
the sheet attaching/detaching control means controls the sheet attaching/detaching means so that, while subjecting the green sheet on the periphery of one drum to processing, the processed green sheet can be detached from the periphery of the other drum in the one non-processing position and the unprocessed green sheet can be attached to it with the sheet attaching/detaching means.

15. The apparatus for manufacturing the multilayer electronic part according to claim 9, wherein:
the laser beam irradiation means has two or more output systems, and their output ends are respectively arranged in a position corresponding to the drums so as to irradiate the laser beam toward the periphery of the processing-side drum;
the sheet attaching/detaching means are respectively arranged in a position corresponding to the drums so as to detach the processed green sheet from the non-processing side drum and attach the unprocessed green sheet to it;
the process control means controls the drum driving means and the laser beam irradiation means so that the green sheet attached to the periphery of the processing-side drum can be irradiated with laser beam from at least one of the output ends of the laser beam irradiation means while allowing the processing-side drum to rotate about the drum's centerline as the axis and travel in the drum's centerline direction; and
the sheet attaching/detaching control means controls the sheet attaching/detaching means so that, while subjecting the green sheet on the periphery of the processing-side drum, the processed green sheet can be detached from the periphery of the non-processing-side drum and the unprocessed green sheet can be attached to it with the sheet attaching/detaching means.

16. The apparatus for manufacturing the multilayer electronic part according to claim 9, wherein:
the processing apparatus comprises a translatable table having one or more sheet attaching/detaching means arranged thereon and a table driving means allowing the table to travel in such a manner that the sheet attaching/detaching means corresponds to the non-processing-side drum;
the laser beam irradiation means has two or more output systems, and their output ends are respectively arranged in a position corresponding to the drums so as to irradiate the laser beam toward the periphery of the processing-side drum;
the process control means controls the drum driving means and the laser beam irradiation means so that the green sheet attached to the periphery of the processing-side drum can be irradiated with the laser beam from at least one of the output ends of the laser beam irradiation means while allowing the processing-side drum to rotate about the drum's centerline as the axis and travel in the drum's centerline direction; and
the sheet attaching/detaching control means controls the sheet attaching/detaching means and the table driving means so that, while subjecting the green sheet on the periphery of the processing-side drum, the sheet attaching/detaching means is allowed to travel in such a manner as to correspond to the non-processing side drum, then detach the processed green sheet from the periphery of the non-processing-side drum and attach the unprocessed green sheet to it.
